(19) United States
(12) Patent Application Publication
(10) Pub. No.: US 2024/0068126 A1
(43) Pub. Date: Feb. 29, 2024

(54) METHOD OF MANUFACTURING MONOCRYSTALLINE SILICON

(71) Applicant: SUMCO CORPORATION, Tokyo (JP)

(72) Inventors: Fukuo OGAWA, Nagasaki (JP); Hiroyuki OTA, Nagasaki (JP); Takashi OHARA, Nagasaki (JP)

(73) Assignee: SUMCO CORPORATION, Tokyo (JP)

(21) Appl. No.: 18/237,001

(22) Filed: Aug. 23, 2023

(30) Foreign Application Priority Data
Aug. 24, 2022 (JP) 2022-133498

(51) Int. Cl. C30B 29/06; C30B 15/10; C30B 15/16; C30B 15/20

(52) U.S. Cl. CPC C30B 29/06; C30B 15/10; C30B 15/16; C30B 15/20; C30B 15/30

(57) ABSTRACT

A method of manufacturing monocrystalline silicon is provided, the method including pulling monocrystalline silicon out of a silicon melt by a Czochralski process, the silicon melt being stored in a crucible housed in a chamber, the silicon melt being added with a volatile dopant, in which a decompression rate ES for exhaust of a gas out of the chamber before the pulling of the monocrystalline silicon is within a range below at least until a pressure inside the chamber decreases from an atmospheric pressure to 80 kPa, 0 kPa/min<ES≤4.2 kPa/min.

### CROSS REFERENCE TO RELATED APPLICATIONS

The entire disclosure of Japanese Patent Application No. 2022-133498 filed Aug. 24, 2022 is expressly incorporated by reference herein.

### TECHNICAL FIELD

The present invention relates to a method of manufacturing monocrystalline silicon.

### BACKGROUND ART

For manufacturing of monocrystalline silicon including pulling monocrystalline silicon out of a silicon melt by a Czochralski process, it is typical that the inside of a chamber is decompressed using a vacuum pump before pulling of the monocrystalline silicon and then an inert gas such as an argon gas is introduced to produce an inert gas atmosphere inside the chamber.

In addition, to reduce a resistance value of the monocrystalline silicon, a dopant is added to the silicon melt. Volatile dopants such as red phosphorus, arsenic, and antimony are known as dopants able to lower a resistivity of monocrystalline silicon.

Meanwhile, it is known that monocrystalline silicon with a low resistivity is likely to suffer occurrence of dislocations during pulling (see, for instance, Patent Literature 1: JP 2021-35907 A).

Occurrence of dislocations during pulling of monocrystalline silicon makes it necessary to melt already grown monocrystalline silicon again and perform pulling again.

### SUMMARY OF THE INVENTION

An object of the invention is to provide a method of manufacturing monocrystalline silicon including pulling monocrystalline silicon out of a silicon melt added with a volatile dopant by a Czochralski process, the method being able to reduce occurrence of dislocations.

A method of manufacturing monocrystalline silicon according to an aspect of the invention includes pulling monocrystalline silicon out of a silicon melt by a Czochralski process, the silicon melt being stored in a crucible housed in a chamber, the silicon melt being added with a volatile dopant, in which a decompression rate ES for exhaust of a gas out of the chamber before the pulling of the monocrystalline silicon is within a range below at least until a pressure inside the chamber decreases from an atmospheric pressure to 80 kPa.

0 kPa/min<ES≤4.2 kPa/min

In the method of manufacturing monocrystalline silicon, it is preferable that the decompression rate ES be within a range below at least until the pressure inside the chamber decreases from the atmospheric pressure to 80 kPa.

2.0 kPa/min≤ES≤4.2 kPa/min

In the method of manufacturing monocrystalline silicon, it is preferable that in response to the pressure inside the chamber falling below 80 kPa, the decompression rate ES be set higher than 4.2 kPa/min.

### BRIEF DESCRIPTION OF DRAWINGS

FIG. 1 is a cross-sectional view illustrating a schematic configuration of a monocrystalline silicon pull-up device according to an exemplary embodiment of the invention.

FIG. 2 is a flowchart for explaining a method of manufacturing monocrystalline silicon according to an exemplary embodiment of the invention.

FIG. 3 is a graph showing a change in a pressure inside a chamber at the start of vacuum exhaust.

### DETAILED DESCRIPTION

Description will be made on a mode for carrying out the invention with reference to the attached drawings.

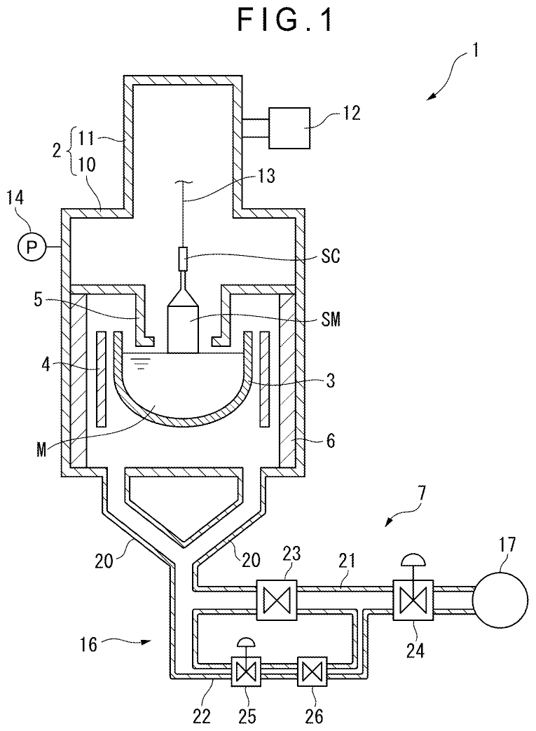

FIG. 1 is a cross-sectional view illustrating a schematic configuration of a monocrystalline silicon pull-up device 1 according to an exemplary embodiment of the invention. The monocrystalline silicon pull-up device 1 is a device for manufacturing monocrystalline silicon SM by using a Czochralski process.

As illustrated in FIG. 1, the monocrystalline silicon pull-up device 1 includes a chamber 2, a crucible 3, a heater 4, a heat shield 5, a heat insulation material 6, and an exhaust device 7.

Although not illustrated in FIG. 1, the monocrystalline silicon pull-up device 1 includes a driver that causes the crucible 3 to rotate and move up and down and a puller that pulls the monocrystalline silicon SM by causing a seed crystal SC to be immersed into a silicon melt M in the crucible 3 through a cable 13 and then pulling the seed crystal SC while rotating the seed crystal SC in a predetermined direction.

The chamber 2 includes a main chamber 10 used for pulling of the monocrystalline silicon SM and a pull chamber 11 coupled to an upper portion of the main chamber 10 and in which the pulled monocrystalline silicon SM is to be received.

The pull chamber 11 is provided with a gas introducer 12 that introduces an inert gas such as an argon (Ar) gas into the chamber 2.

In addition, the chamber 2 is provided with a pressure gauge 14 that measures a pressure inside the chamber 2.

The crucible 3 is substantially in a form of a bottomed cylinder and is able to be housed inside the main chamber 10. The silicon melt M is stored in the crucible 3.

The heater 4 is located outside the crucible 3 at a predetermined distance in between and heats a silicon feedstock and the silicon melt M in the crucible 3.

The heat shield 5 is provided to surround the pulled monocrystalline silicon SM and blocks radiation heat from the heater 4 to the monocrystalline silicon SM.

The exhaust device 7 is a device that causes gas inside the chamber 2 to be exhausted to reduce the pressure inside the chamber 2. The exhaust device 7 includes a piping section 16 and an exhaust pump 17 that causes the gas inside the chamber 2 to be exhausted through the piping section 16.

The piping section 16 includes a plurality of branch pipes 20, a first pipe 21 coupled downstream of the plurality of branch pipes 20 (on the opposite side to the chamber 2), and a second pipe 22 bypassing a part of the first pipe 21. Ends of the plurality of branch pipes 20 are coupled to the chamber 2. The other ends of the plurality of branch pipes 20 are collectively coupled to the first pipe 21.

The number of the branch pipes 20 of the exemplary embodiment is four (only two of them are illustrated in FIG. 1) and the branch pipes 20 are arranged at regular intervals in a circumferential direction of the chamber 2; however, the number of the branch pipes 20 is not limited to the above. Alternatively, the first pipe 21 may be directly coupled to the chamber 2 without providing the branch pipes 20.

The first pipe 21 is provided with a first valve 23 and a first flow rate regulating valve 24. The first valve 23 is a valve mainly having a function to cut off the first pipe 21. The first valve 23 of the exemplary embodiment is provided near the chamber 2 with respect to the first flow rate regulating valve 24 but this is not limiting.

The second pipe 22 is a pipe branched from the first pipe 21 and again coupled to the first pipe 21. The second pipe 22 is branched from a portion of the first pipe 21 between the chamber 2 and the first valve 23 and coupled to a portion of the first pipe 21 between the first valve 23 and the first flow rate regulating valve 24.

The second pipe 22 is provided with a second flow rate regulating valve 25 and a second valve 26. The second flow rate regulating valve 25 of the exemplary embodiment is located upstream of the second valve 26 (near the chamber 2) but this is not limiting.

The second valve 26 is a valve mainly having a function to cut off the second pipe 22.

Valves having a function to cut off a pipe, such as a ball valve, a needle valve, a gate valve, and a globe valve, are usable as the first valve 23 and the second valve 26.

The first flow rate regulating valve 24 and the second flow rate regulating valve 25 are valves that regulate flow rates of gas flowing through the pipes 21, 22 in accordance with a change in an opening/closing degree.

The flow rate regulating valves 24, 25 of the exemplary embodiment are butterfly valves. Specifications of the butterfly valves are selected on the basis of inner diameters of the pipes 21, 22 and the second flow rate regulating valve 25 is more suitable for regulation of a small flow rate than the first flow rate regulating valve 24.

It should be noted that the flow rate regulating valves 24, 25 only have to regulate the flow rates of the gas flowing through the pipes 21, 22 and valves such as a needle valve, a gate valve, a globe valve, and a ball valve are usable in addition to a butterfly valve.

The second pipe 22 is formed to have an inner diameter smaller than the inner diameter of the first pipe 21.

The first pipe 21 and the second pipe 22 are formed to satisfy Expression (1) below, where the inner diameter of the first pipe 21 is D1 and the inner diameter of the second pipe 22 is D2.

⅕≤D2/D1≤⅗ (1)

The inner diameter of the first pipe 21 can be, for instance, 100 mm, and the inner diameter of the second pipe 22 can be, for instance, 50 mm.

The inner diameter of the second pipe 22 is not necessarily smaller throughout an entire length of the second pipe 22 than the inner diameter of the first pipe 21 and it is sufficient if at least a portion of the second pipe 22 that is provided with the second flow rate regulating valve 25 has an inner diameter smaller than the inner diameter of the first pipe 21.

### Method of Manufacturing Monocrystalline Silicon

Now, description will be made on a method of manufacturing monocrystalline silicon by using the above-described monocrystalline silicon pull-up device 1.

The invention is favorable to manufacturing of an n-type monocrystalline silicon with a considerably low electrical resistivity; the invention is favorable to manufacturing of an n-type monocrystalline silicon having an electrical resistivity in a range from 5 mΩ·cm to 20 mΩ·cm in a case where an n-type dopant (a volatile dopant) is antimony (Sb), 1.2 mΩ·cm to 10 mΩ·cm in a case where the n-type dopant is arsenic (As), and 0.5 mΩ·cm to 5 mΩ·cm in a case where the n-type dopant is red phosphorus (P).

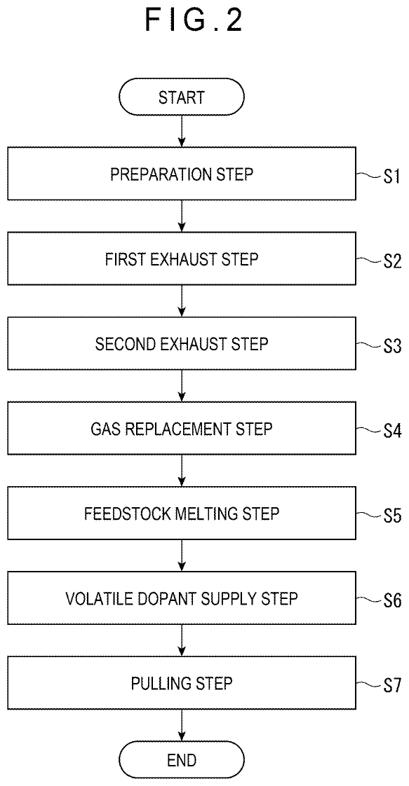

As illustrated in FIG. 2, the method of manufacturing monocrystalline silicon includes a preparation step S1, a first exhaust step S2, a second exhaust step S3, a gas replacement step S4, a feedstock melting step S5, a volatile dopant supply step S6, and a pulling step S7.

In the preparation step S1, polycrystalline silicon that is a feedstock of monocrystalline silicon is prepared, an appropriate amount of silicon chunks is loaded in the crucible 3, and then the crucible 3 is received in the main chamber 10.

The first exhaust step S2 is a step of reducing the pressure inside the chamber 2 from a state of atmospheric pressure (101.325 kPa) by exhausting the gas inside the chamber 2 before pulling of the monocrystalline silicon SM. Although it is preferable that the exhaust be rapidly performed in terms of production efficiency, a decompression rate of the gas is intendedly lowered in the first exhaust step S2.

In the first exhaust step S2, the first valve 23 of the first pipe 21 is in a closed state and the second valve 26 of the second pipe 22 is in an open state. In addition, the first flow rate regulating valve 24 of the first pipe 21 is in an open state. In short, the gas inside the chamber 2 is exhausted through the second pipe 22.

In the first exhaust step S2, a decompression rate ES of the gas is regulated within a range represented by Expression (2) below by the second flow rate regulating valve 25.

0 kPa/min<ES≤4.2 kPa/min (2)

The regulation of the decompression rate ES by the second flow rate regulating valve 25 is continued at least until the pressure inside the chamber 2 reaches 80 kPa.

Here, description will be made on a method of determining the above-described decompression rate ES.

The inventors speculated that in growing the monocrystalline silicon SM using a volatile dopant, the volatile dopant evaporated from a surface of the silicon melt M during pulling and adhered to the piping section 16 in a form of an amorphous substance, and the amorphous substance flew up and then adhered to the monocrystalline silicon SM to cause polycrystallization of the monocrystalline silicon SM.

In addition, in the monocrystalline silicon pull-up device 1 using a volatile dopant, repetition of pulling caused the amorphous substance to accumulate on the piping section 16.

The inventors speculated that lowering the decompression rate ES (decreasing the decompression rate ES) at the start of pulling made it possible to reduce flying of the amorphous substance to reduce a rate of occurrence of dislocations and performed the following examination accordingly.

The decompression rate ES for the first exhaust step S2 was determined by performing pulling of the monocrystalline silicon for a plurality of times with changes of the decompression rate ES before pulling of the monocrystalline silicon SM and examining whether dislocations occurred.

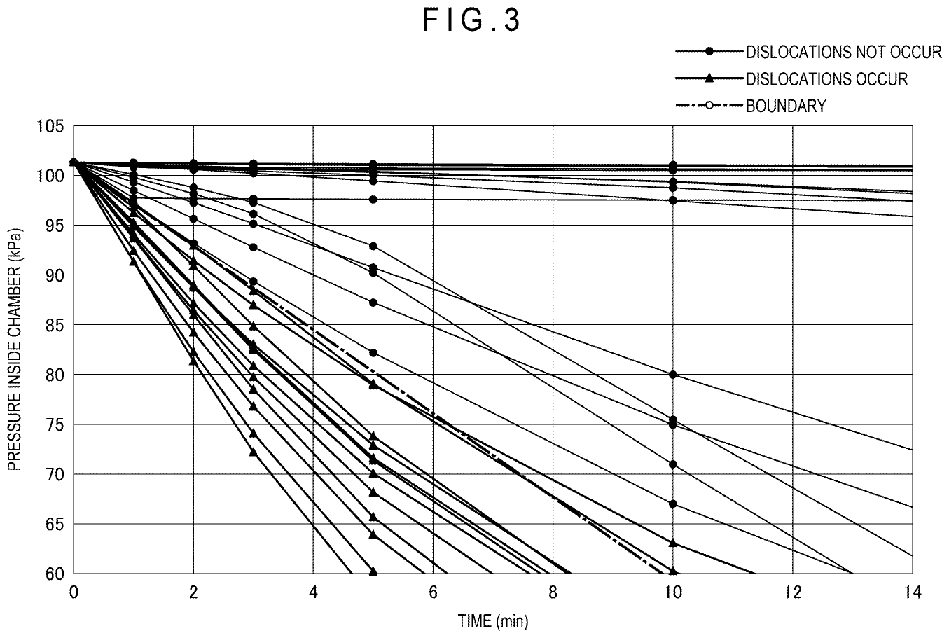

FIG. 3 is a graph showing a change in the pressure inside the chamber In FIG. 3, a horizontal axis represents time (min) and a vertical axis represents the pressure (kPa) inside the chamber.

As shown in FIG. 3, it has been found that a large change in the pressure, that is, a high decompression rate (a large decompression rate), at the start of exhaust leads to occurrence of dislocations, whereas a small change in the pressure, that is, a low decompression rate, at the start of exhaust does not lead to occurrence of dislocations. In other words, it has been found that a rapid reduction in the pressure inside the chamber makes dislocations likely to occur and a moderate reduction in the pressure inside the chamber does not lead to occurrence of dislocations.

It has been found that dislocations are able to be reduced by obtaining a boundary between occurrence and no occurrence of dislocations from an examination result shown in FIG. 3 and setting the decompression rate equal to 4.2 kPa/min or lower than 4.2 kPa/min in accordance with the boundary.

It should be noted that it is preferable that a decompression rate be set high in view of time required for vacuum exhaust and, accordingly, it is preferable that the decompression rate ES be regulated within a range represented by Expression (3) below.

2.0 kPa/min≤ES≤4.2 kPa/min (3)

Such regulation of the decompression rate ES makes it possible to reduce exhaust time and improve the production efficiency of the monocrystalline silicon SM.

The second exhaust step S3 is a step of gradually increasing the decompression rate ES after the pressure inside the chamber 2 reaches 80 kPa and performing exhaust until the pressure becomes close to 0 kPa. In the second exhaust step S3, an opening degree of the second flow rate regulating valve 25 is first gradually increased and the first valve 23 is subsequently set in an open state. In short, switching is performed to cause the gas to be exhausted through the first pipe 21. After the first valve 23 is set in the open state, the second valve 26 may be set in a closed state. At this time, the first flow rate regulating valve 24 allows for fine regulation of the decompression rate ES.

In the second exhaust step S3, exhaust through the first pipe 21 having a larger diameter than the second pipe 22 allows for a rapid exhaust.

The gas replacement step S4 is a step of introducing an inert gas into the vacuum-exhausted chamber 2 to perform replacement with an inert gas atmosphere. The inert gas is to be introduced by the gas introducer 12.

The feedstock melting step S5 is a step of melting the polycrystalline silicon (the silicon feedstock) received in the crucible 3 into the silicon melt M. In the feedstock melting step S5, the crucible 3 is rotated and concurrently heated by the heater 4 in a state where the inert gas atmosphere inside the chamber 2 is maintained, thereby melting the polycrystalline silicon in the crucible 3 to generate the silicon melt M.

In the volatile dopant supply step S6, a dopant supply device (not illustrated) is used to add the volatile dopant to the silicon melt M.

The pulling step S7 is a step of pulling the monocrystalline silicon SM while rotating the monocrystalline silicon SM. In the pulling step S7, the first valve 23 is set in the closed state and the second valve 26 is set in the open state as in the first exhaust step S2 and the pressure inside the chamber 2 is regulated to 60±5 kPa using the second flow rate regulating valve 25. By virtue of thus setting the pressure inside the chamber 2 high, it is possible to reduce evaporation of the volatile dopant.

According to the above exemplary embodiment, the decompression rate ES is set equal to 4.2 kPa/min or lower than 4.2 kPa/min in the first exhaust step S2, which makes the amorphous substance, which is derived from the volatile dopant adhering to the piping section 16, unlikely to fly up. This makes it possible to reduce occurrence of dislocations due to adhesion of the amorphous substance to the monocrystalline silicon SM during pulling.

In addition, in the first exhaust step S2, the gas is exhausted through the second pipe 22 having a smaller diameter than the first pipe 21 with a pipe resistance against the gas flowing through the pipe being increased. This makes it possible to easily lower the decompression rate ES.

In addition, in the second exhaust step S3, the decompression rate ES is set higher than 4.2 kPa/min, which allows for a rapid exhaust and an improvement in production efficiency of the monocrystalline silicon SM.

### Examples

Now, description will be made on an example and a comparative example of the invention.

In the example and the comparative example, pulling of monocrystalline silicon was performed for a plurality of times and a comparison was made in terms of rate of occurrence of dislocations relative to the decompression rate ES at the time of exhaust of the gas out of the chamber before pulling of the monocrystalline silicon. For both the example and the comparative example, a target resistivity of a top of a straight body of the monocrystalline silicon is 2.3 mΩ·cm. Table 1 shows conditions and results.

TABLE 1

| | | Rate of Occurrence |
|---|---|---|
| | Decompression Rate ES | of Dislocations |
| Ex. | ES ≤ 4.2 kPa | 38% |
| Comp. | ES > 4.2 kPa | 100% |

As shown in Table 1, it has been found that the rate of occurrence of dislocations can be reduced even to 38% in the example where the decompression rate ES was set equal to or lower than 4.2 kPa as compared with the comparative example where the decompression rate ES was set higher than 4.2 kPa.

What is claimed is:

1. A method of manufacturing monocrystalline silicon, the method comprising pulling monocrystalline silicon out of a silicon melt by a Czochralski process, the silicon melt being stored in a crucible housed in a chamber, the silicon melt being added with a volatile dopant, wherein
a decompression rate ES for exhaust of a gas out of the chamber before the pulling of the monocrystalline silicon is within a range below at least until a pressure inside the chamber decreases from an atmospheric pressure to 80 kPa,
0 kPa/min<ES≤4.2 kPa/min.

2. The method of manufacturing monocrystalline silicon according to claim 1, wherein
the decompression rate ES is within a range below at least until the pressure inside the chamber decreases from the atmospheric pressure to 80 kPa,
2.0 kPa/min≤ES≤4.2 kPa/min.

3. The method of manufacturing monocrystalline silicon according to claim 1, wherein
in response to the pressure inside the chamber falling below 80 kPa, the decompression rate ES is set higher than 4.2 kPa/min.
